(19) United States
(12) Patent Application Publication
(10) Pub. No.: US 2025/0048860 A1
(43) Pub. Date: Feb. 6, 2025

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yuge CHU, Beijing (CN); Tingliang LIU, Beijing (CN); Siyu WANG, Beijing (CN); Yuanjie XU, Beijing (CN); Jianmin YE, Beijing (CN); Yi ZHANG, Beijing (CN)

(21) Appl. No.: 18/580,129

(22) PCT Filed: Apr. 11, 2023
(86) PCT No.: PCT/CN2023/087486

§ 371 Date: Jan. 17, 2024

(30) Foreign Application Priority Data
Apr. 18, 2022 (CN) 202210405966.8

(51) Int. Cl. H10K 59/131; H10K 59/12; H10K 59/121

(52) U.S. Cl. CPC H10K 59/131; H10K 59/1201; H10K 59/1213

(57) ABSTRACT

Provided is a display panel. The display panel includes: a substrate including a light-transmitting display region and a conventional display region; a plurality of first pixel drive circuits, a plurality of first connecting lines, and a plurality of first light-emitting devices disposed in the conventional display region, wherein the first connecting line comprises a connection line part and a compensation part electrically connected to each other, the compensation part being configured to increase an area of the first connecting line; and a plurality of second pixel drive circuits disposed in the conventional display region, a plurality of second connecting lines disposed on the substrate, and a plurality of second light-emitting devices disposed in the light-transmitting display region.

### CROSS-REFERENCE TO RELATED APPLICATION

This application is a U.S. national stage of international application No. PCT/CN2023/087486, filed on Apr. 11, 2023, which claims priority to Chinese Patent Application No. 202210405966.8, filed on Apr. 18, 2022, and entitled “DISPLAY PANEL AND DISPLAY DEVICE”, the disclosures of which are herein incorporated by reference in their entireties.

### TECHNICAL FIELD

The present disclosure relates to the field of display technologies, and in particular to a display panel and a display device.

### BACKGROUND

At present, a display device usually includes a photosensitive sensor such as an image sensor for achieving a photographing function, a biometric recognition function, or the like.

### SUMMARY

The embodiments of the present disclosure provide a display panel and a display device. The technical solutions are as follows.

According to one aspect of the present disclosure, a display panel is provided. The display panel includes:
a substrate, wherein the substrate includes a light-transmitting display region and a conventional display region at a periphery of the light-transmitting display region;
a plurality of first pixel drive circuits, a plurality of first connecting lines, and a plurality of first light-emitting devices disposed in the conventional display region, wherein the first light-emitting devices are electrically connected to the first pixel drive circuits through the first connecting lines, and the first connecting line includes a connection line part and a compensation part electrically connected to each other, the compensation part being configured to increase the area of the first connecting line; and
a plurality of second pixel drive circuits disposed in the conventional display region, a plurality of second connecting lines disposed on the substrate, and a plurality of second light-emitting devices disposed in the light-transmitting display region, wherein the second light-emitting devices are electrically connected to the second pixel drive circuits through the second connecting lines.

In some embodiments, the plurality of second connecting lines include a target connecting line, wherein a length of the target connecting line is a median of lengths of the plurality of second connecting lines; and
a ratio of the area of the first connecting line to the area of the target connecting line ranges from 60% to 130%.

In some embodiments, the plurality of second connecting lines include a target connecting line, wherein the length of the target connecting line is a mean value of the lengths of the plurality of second connecting lines; and
a ratio of the area of the first connecting line to an area of the target connecting line ranges from 60% to 130%.

In some embodiments, the connection line part includes a first sub-connecting line and a second sub-connecting line, wherein one end of the first sub-connecting line is connected to the first pixel drive circuit, one end of the second sub-connecting line is electrically connected to the first light-emitting device, and the compensation part is respectively in contact with and electrically connected to the other end of the first sub-connecting line and the other end of the second sub-connecting line.

In some embodiments, the compensation part includes a threadlike compensation part, wherein a shape of the threadlike compensation part includes at least one of an S-shaped winding shape and a polyline shape.

In some embodiments, the compensation part includes a block-shaped compensation part, wherein a shape of the block-shaped compensation part includes at least one of a rectangle, a triangle, a circle, and a hexagon.

In some embodiments, the display panel further includes a first insulating layer and a second insulating layer, wherein the first pixel drive circuits, the first insulating layer, the first connecting lines, the second insulating layer, and the first light-emitting devices are stacked in a direction away from the substrate; and
the first insulating layer is provided with a first via hole through which the first connecting line is electrically connected to the first pixel drive circuit, and the second insulating layer is provided with a second via hole through which the first connecting line is electrically connected to the first light-emitting device; wherein
a distance between the first via hole and the second via hole in a plane perpendicular to a thickness direction of the substrate is greater than or equal to 25 microns.

In some embodiments, the first connecting line further includes an extension part, wherein the extension part is disposed on a side, distal from the compensation part, of the first sub-connecting line, and the extension part is electrically connected to the first sub-connecting line; and
the shape of the extension part includes at least one of a rectangle, a triangle, a circle, a hexagon, a straight-line shape, an S-shaped winding shape, and a polyline shape.

In some embodiments, the connection line part and the compensation part are in a same layer.

In some embodiments, the connection line part, the compensation part, and the extension part are in a same layer.

In some embodiments, the display panel further includes a first insulating layer, wherein the first pixel drive circuits, the first insulating layer, and the first connecting lines are stacked in a direction away from the substrate; and
a side, distal from the substrate, of the first insulating layer is provided with a groove, and at least part of the first connecting line is disposed in the groove.

In some embodiments, an orthogonal projection of the first connecting line on the substrate overlaps with an orthogonal projection of the groove on the substrate.

In some embodiments, a thickness of the first connecting line is the same as a depth of the groove.

In some embodiments, the first pixel drive circuit includes a plurality of thin film transistors, wherein the first light-emitting device is electrically connected to at least one of the plurality of thin film transistors, and an orthogonal projection of the first connecting line on the substrate has an overlapping area with orthogonal projections of one or more of the plurality of thin film transistors on the substrate.

In some embodiments, the display panel further includes a target trace, wherein the target trace is disposed on a side, proximal to the substrate, of the first insulating layer, and an orthographic projection of the first connecting line on the substrate has an overlapping area with an orthographic projection of the target trace on the substrate.

According to another aspect of the present disclosure, a method for manufacturing a display panel is provided. The method includes:
forming a plurality of first pixel drive circuits and a plurality of second pixel drive circuits in a conventional display region on a substrate;
forming a plurality of first connecting lines and a plurality of second connecting lines on the substrate having the plurality of first pixel drive circuits and the plurality of second pixel drive circuits formed thereon, the first connecting line including a connection line part and a compensation part, the compensation part being configured to increase an area of the first connecting line; and
forming a plurality of first light-emitting devices and a plurality of second light-emitting devices on the substrate having the first connecting lines and the second connecting lines formed thereon, the first light-emitting devices being disposed in the conventional display region of the substrate, and the second light-emitting devices being disposed in a light-transmitting display region of the substrate;
wherein the first light-emitting devices are electrically connected to the first pixel drive circuits through the first connecting lines, and the second light-emitting devices are electrically connected to the second pixel drive circuits through the second connecting lines.

In some embodiments, forming the plurality of first connecting lines and the plurality of second connecting lines includes:
forming a first insulating material layer on the substrate having the plurality of first pixel drive circuits and the plurality of second pixel drive circuits formed thereon;
forming a first insulating layer by forming a plurality of grooves and a plurality of first via holes on the first insulating material layer through a single masking process; and
forming the plurality of first connecting lines and the plurality of second connecting lines on the substrate having the first insulating layer formed thereon, at least part of the first connecting line being disposed in the groove.

In some embodiments, forming the plurality of first connecting lines on the substrate having the first insulating layer formed thereon includes:
forming the plurality of first connecting lines by forming, through one patterning process, a plurality of the connection line parts and a plurality of the compensation parts on the substrate having the first insulating layer formed thereon.

In some embodiments, forming the plurality of first light-emitting devices and the plurality of second light-emitting devices on the substrate having the first connecting lines and the second connecting lines formed thereon includes:
forming a second insulating layer on the substrate having the first connecting lines and the second connecting lines formed thereon, the second insulating layer being provided with a second via hole; and
forming the plurality of first light-emitting devices and the plurality of second light-emitting devices on the substrate having the second insulating layer formed thereon.

According to yet another aspect of the present disclosure, a display device is provided. The display device includes: a photosensitive sensor and the display panel described above, wherein an orthographic projection of a light inlet surface of the photosensitive sensor on the substrate of the display panel is within the light-transmitting display region.

### BRIEF DESCRIPTION OF THE DRAWINGS

For clearer descriptions of the technical solutions according to the embodiments of the present disclosure, the drawings to be referred to for the description of the embodiments are briefly introduced below. Apparently, the drawings in the description below merely illustrate some embodiments of the present disclosure, and those skilled in the art may also derive other drawings according to the drawings without creative efforts.

FIG. 1 is a schematic structural diagram of a display panel;

FIG. 2 is a schematic structural diagram of a part of the display panel shown in FIG. 1;

FIG. 3 is a schematic structural diagram of a display panel according to some embodiments of the present disclosure;

FIG. 4 is a schematic structural diagram of a part of the display panel shown in FIG. 3;

FIG. 5 is a schematic structural diagram of a first connecting line according to some embodiments of the present disclosure;

FIG. 6 is a schematic structural diagram of a second connecting line according to some embodiments of the present disclosure;

FIG. 7 is a schematic structural diagram of another first connecting line on the display panel according to some embodiments of the present disclosure;

FIG. 8 is a schematic cross-sectional view of the display panel shown in FIG. 7 along A1-A2;

FIG. 9 is a schematic structural diagram of another display panel according to an embodiment of the present disclosure;

FIG. 10 is another schematic cross-sectional view of the display panel shown in FIG. 7 along A1-A2;

FIG. 11 is a circuit schematic diagram of a first pixel drive circuit according to some embodiments of the present disclosure;

FIG. 12 is a flowchart of a method for manufacturing a display panel according to some embodiments of the present disclosure;

FIG. 13 is a flowchart of yet another display panel according to some embodiments of the present disclosure; and

FIG. 14 is a flowchart of a method for forming a plurality of first connecting lines and a plurality of second connecting lines according to some embodiments of the present disclosure.

The above drawings have shown the explicit embodiments of the present disclosure, which are described hereinafter in detail. These drawings and text descriptions are not intended to limit the scope of the conception of the present disclosure in any way, but to illustrate the concept of the present disclosure to those skilled in the art with reference to specific embodiments.

### DETAILED DESCRIPTION

For clearer descriptions of the objects, technical solutions, and advantages of the present disclosure, embodiments of the present disclosure are further described in detail hereinafter with reference to the drawings.

In some practices, for some display devices, the screen-to-body ratio of the display device is improved by providing a light-transmitting display region capable of transmitting light and displaying images on a display panel, and by arranging an image sensor on the back surface of the light-transmitting display region of the display panel.

A display panel includes: a light-transmitting display region and a conventional display region disposed around the light-transmitting display region. Light-emitting devices in the light-transmitting display region may be electrically connected to pixel drive circuits in the conventional display region to enable the light-transmitting display region to have a display function and a light-transmitting function.

However, the display panel has a poor display effect.

At present, a method for improving the screen-to-body ratio of a display device is setting a display panel in the display device to be a partially light-transmitting display panel so as to improve the screen-to-body ratio of the display device. That is, the display panel includes a light-transmitting display region and a conventional display region at the periphery of the light-transmitting display region. The light-transmitting display region is also referred to as a full display with camera (FDC) region. The conventional display region and the light-transmitting display region are both provided with light-emitting devices, such that both the conventional display region and the light-transmitting display region are capable of displaying pictures.

In the display panel, the pixel drive circuits disposed in arrays in the conventional display region are compressed in the row direction and/or the column direction, such that more pixel drive circuits are disposed in the conventional display region, and the additional pixel drive circuits are electrically connected to the light-emitting devices in the light-transmitting display region to drive the light-emitting devices in the light-transmitting display region.

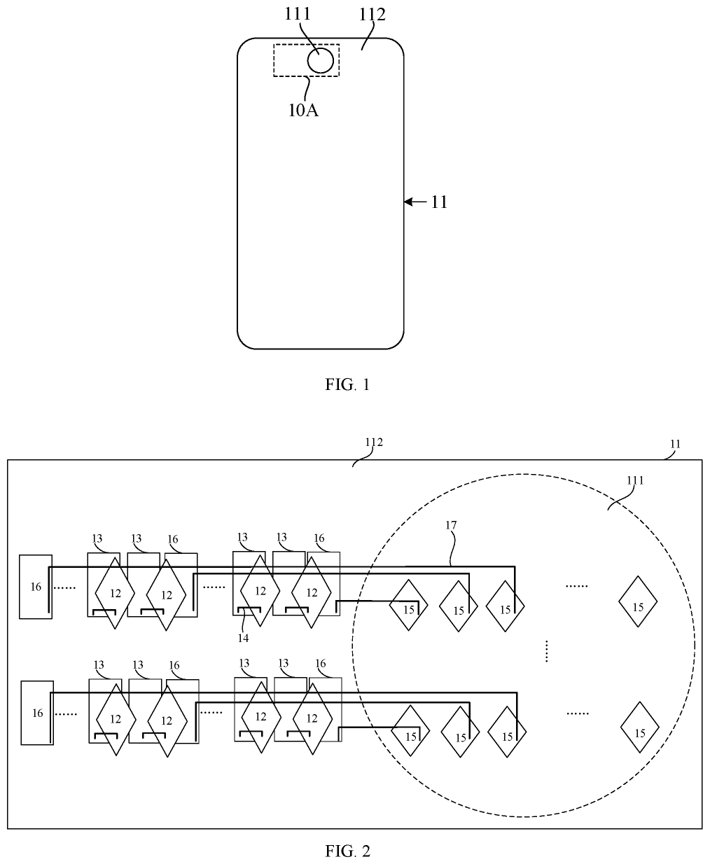

Referring to FIGS. 1 and 2, FIG. 1 is a schematic structural diagram of a display panel, and FIG. 2 is a schematic structural diagram of a part 10A of the display panel shown in FIG. 1. The display panel includes: a substrate 11, wherein the substrate 11 includes a light-transmitting display region 111 and a light-tight conventional display region 112.

The conventional display region 112 is provided with a plurality of first light-emitting devices 12 and a plurality of first pixel drive circuits 13, the first light-emitting devices 12 being electrically connected to the first pixel drive circuits 13 through first connecting lines 14. Also, an orthographic projection of the first light-emitting device 12 on the substrate 11 at least partially overlaps with an orthographic projection of the first pixel drive circuit 13 on the substrate 11.

The light-transmitting display region 111 is provided with a plurality of second light-emitting devices 15, and the conventional display region 112 is provided with a second pixel drive circuit 16 electrically connected to the second light-emitting device 15 in the light-transmitting display region 111. The second light-emitting device 15 is electrically connected, through the second connecting line 17, to the second pixel drive circuit 16.

Because the distance between the first light-emitting device 12 and the first pixel drive circuit 13 is smaller than the distance between the second light-emitting device 15 and the second pixel drive circuit 16, the length of the first connecting line 14 is smaller than the length of the second connecting line 17, resulting in that the parasitic capacitance corresponding to the first connecting line 14 is smaller than the parasitic capacitance corresponding to the second connecting line 17, and the lighting time of the first light-emitting device 12 electrically connected to the first connecting line 14 is different from the lighting time of the second light-emitting device 15 electrically connected to the second connecting line 17. Parasitic capacitance refers to a capacitance between the first connecting line 14 or the second connecting line 17 and other conductive structures (e.g., a power line or a pixel electrode) on the display panel 10. The parasitic capacitance is an inevitable capacitance generated due to two conductive structures being close to each other, and is present between various conductive structures of the display panel.

In the case that a drive current generated by the pixel drive circuit drives the light-emitting device, the connecting line is charged first, and then the light-emitting device is lighted; namely, the start-up of the light-emitting device is not instantaneous, and a start-up process is present. In some embodiments, the lighting time refers to the duration between a moment at which the pixel drive circuit emits the drive current and a moment at which the light-emitting devices are lighted. That is, in the case that the drive current generated by the pixel drive circuit drives the light-emitting device, the connecting line is charged first, then the light-emitting device is lighted, and thus the lighting time of the first light-emitting device 12 electrically connected to the first connecting line 14 and the lighting time of the second light-emitting devices 15 electrically connected to the second connecting line 17 are not uniform.

Illustratively, in the case that the display panel 10 provides the same signal to the first pixel drive circuits 13 and the second pixel drive circuits 16, the charging or discharging speed of the first light-emitting devices 12 electrically connected to the first pixel drive circuits 13 is faster than the charging or discharging speed of the second light-emitting devices 15 electrically connected to the second pixel drive circuits 16, thereby causing a large difference between the lighting time of the first light-emitting devices 12 and the lighting time of the second light-emitting devices 15, i.e., causing the luminance of the first light-emitting devices 12 and the luminance of the second light-emitting devices 15 to be different, and further causing the display uniformity of the light-transmitting display region 111 and the conventional display region 112 of the display panel 10 to be poor.

Embodiments of the present disclosure provide a display panel and a display device, which can solve the problems in the practices described above.

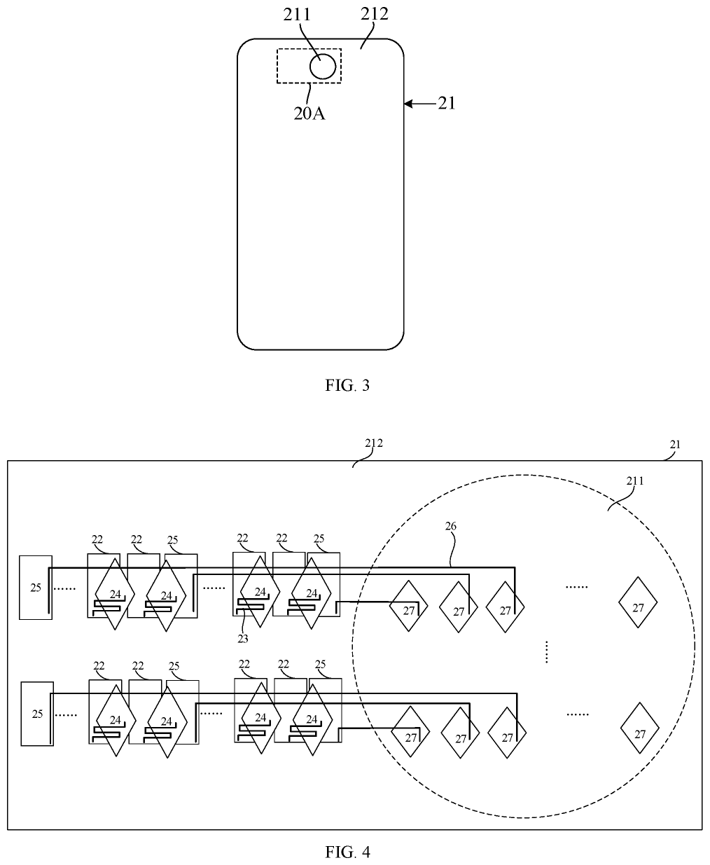

Referring to FIGS. 3 and 4, FIG. 3 is a schematic structural diagram of a display panel according to some embodiments of the present disclosure, and FIG. 4 is a schematic structural diagram of part 20A of the display panel shown in FIG. 3. The display panel 20 includes: a substrate 21, a plurality of first pixel drive circuits 22, a plurality of first connecting lines 23, a plurality of first light-emitting devices 24, a plurality of second pixel drive circuits 25, a plurality of second connecting lines 26, and a plurality of second light-emitting devices 27.

The substrate 21 includes a light-transmitting display region 211 and a conventional display region 212 at the periphery of the light-transmitting display region 211. In some embodiments, the conventional display region 212 surrounds the light-transmitting display region 211, that is, the light-transmitting display region 211 is surrounded by the conventional display region 212. The disposition position of the light-transmitting display region 211 is determined as needed. In some embodiments, the light-transmitting display region 211 is disposed at the right middle position on the top of the substrate 21. Hardware such as a photosensitive sensor (e.g., a camera) is disposed in the light-transmitting display region 211 of the display panel. The shape of the light-transmitting display region 211 includes a circle as shown in FIG. 3, or a square, a hexagon, a trapezoid, and other shapes, which are not limited in the embodiments of the present disclosure.

In some embodiments, the plurality of first pixel drive circuits 22, the plurality of first connecting lines 23, and the plurality of first light-emitting devices 24 are disposed in the conventional display region 212, and the first light-emitting device 24 is electrically connected to the first pixel drive circuit 22 through the first connecting line 23.

In some embodiments, the plurality of second pixel drive circuits 25 are disposed in the conventional display region 212, the plurality of second connecting lines 26 are disposed on the substrate 21, the plurality of second light-emitting devices 27 are disposed in the light-transmitting display region 211, and the second light-emitting devices 27 are electrically connected to the second pixel drive circuits 25 through the second connecting lines 26. That is, part of the second connecting line 26 is disposed in the light-transmitting display region 211, and the other part of the second connecting line is disposed in the conventional display region 212 to electrically connect the second light-emitting device 27 in the light-transmitting display region 211 to the second pixel drive circuit 25 in the conventional display region 212. In this way, the light transmittance of the light-transmitting display region 211 is improved, that is, the light transmittance of the light-transmitting display region 211 is improved in such a manner that the second light-emitting device 27 and the second pixel drive circuit 25 are separately disposed. Also, in some embodiments, the plurality of second pixel drive circuits 25 are disposed around the light-transmitting display region 211 such that the lengths of the second connecting lines 26 are short.

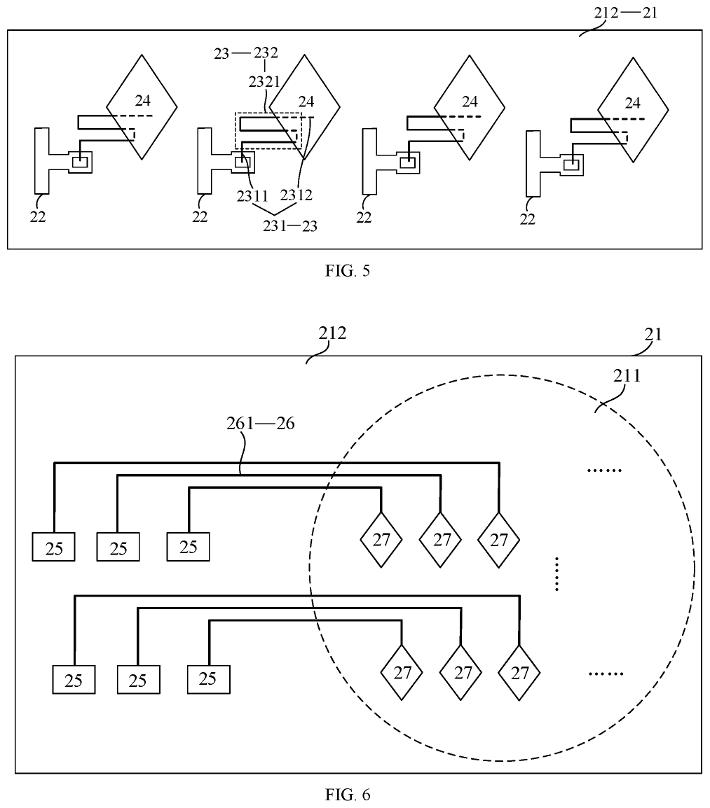

As shown in FIG. 5, which is a schematic structural diagram of a first connecting line according to some embodiments of the present disclosure, the first connecting line 23 includes a connection line part 231 and a compensation part 232 electrically connected to each other, the compensation part 232 being configured to increase the area of the first connecting line 23. In FIG. 5, the part of the first connecting line 23 in the dashed line frame is the compensation part 232, and the part outside the dashed line frame is the connection line part 231, wherein the dashed line segment of the first connecting line 23 indicates that the orthographic projection of the corresponding part of the first connecting line 23 on the substrate 21 overlaps with the orthographic projection of the first light-emitting device 24 on the substrate 21, and the corresponding part of the first connecting line 23 is on a side, proximal to the substrate 21, of the first light-emitting device 24.

In this way, the compensation part 232 is capable of compensating the parasitic capacitance corresponding to the first connecting line 23, such that the difference value between the parasitic capacitance corresponding to the first connecting line 23 electrically connected to the first pixel drive circuit 22 and the parasitic capacitance corresponding to the second connecting line 26 electrically connected to the second pixel drive circuit 25 is small. Therefore, the difference between the lighting time of the first light-emitting device 24 electrically connected to the first pixel drive circuit 22, and the lighting time of the second light-emitting device 27 electrically connected to the second pixel drive circuit 25 is small, and then the difference between the luminance exhibited by the first light-emitting device 24 and the luminance exhibited by the second light-emitting device 27 is small, thereby improving the display uniformity of the light-transmitting display region 211 and the conventional display region 212 of the display panel 20. It is possible to avoid a case that the difference between the lighting time of the first light-emitting device 24 and the lighting time of the second light-emitting device 27 is large because the distance between the first light-emitting device 24 and the first pixel drive circuit 22 is smaller than the distance between the second light-emitting device 27 and the second pixel drive circuit 25.

It should be noted that, in FIG. 4, for convenience of distinguishing the light-transmitting display region 211 from the conventional display region 212, the light-emitting devices at the junction of the light-transmitting display region 211 and the conventional display region 212 are not completely shown, and in an actual display panel, the junction of the light-transmitting display region 211 and the conventional display region 212 includes a plurality of light-emitting devices, and the plurality of light-emitting devices belong to the light-transmitting display region 211 or the conventional display region 212. FIG. 4 only shows a connection mode of electrically connecting some of the plurality of light-emitting devices to the pixel drive circuits. In some embodiments, a connection mode between the other light-emitting devices and the other pixel drive circuits is the same as this connection mode. In FIG. 4, in order to more completely show the shapes of the first connecting line 23 and the second connecting line 26, the schematic diagrams of the first connecting line 23 and the second connecting line 26 are shown to be upper than other structures (light-emitting devices), in the structure of the actual display panel 20, the first connecting line 23 and the second connecting line 26 are disposed on a side, proximal to the substrate 21, of the light-emitting devices (the first light-emitting device 24 and the second light-emitting device 27), that is, the first connecting line 23 and the second connecting line 26 are disposed on the lower layer of the light-emitting devices.

In some embodiments, the first pixel drive circuit 22 includes a plurality of thin film transistors, and FIG. 5 shows a schematic structure diagram of only one thin film transistor in the first pixel drive circuit 22 electrically connected to the first connecting line 23 for clarity of showing the structure of the first connecting line 23.

In summary, the embodiments of the present disclosure provide a display panel. The display panel includes: a plurality of first pixel drive circuits, a plurality of second pixel drive circuits, a plurality of first connecting lines, and a plurality of first light-emitting devices disposed in a conventional display region of a substrate, a plurality of second connecting lines disposed on the substrate, and a plurality of second light-emitting devices disposed in a light-transmitting display region of the substrate. The first connecting line includes a connection line part and a compensation part electrically connected to each other. The area of the first connecting line is increased through the compensation part, and the parasitic capacitance corresponding to the first connecting line is compensated, such that the difference value of the parasitic capacitance corresponding to the first connecting line and the parasitic capacitance corresponding to the second connecting line is reduced, thereby making the difference between the lighting time of the first light-emitting device electrically connected to the first pixel drive circuit and the lighting time of the second light-emitting device electrically connected to the second pixel drive circuit small. In this way, the display uniformity of the display panel is improved, and then the display effect of the display panel can be improved.

In some embodiments of the present disclosure, the first light-emitting device 24 and the second light-emitting device 27 are organic light-emitting diodes (OLED). The organic light-emitting diode at least includes: an anode, a light-emitting layer, and a cathode which are stacked in a direction perpendicular to and away from the substrate 21.

In some embodiments, the anode of the second light-emitting device 27 is electrically connected, through the second connecting line 26, to the second pixel drive circuit 25. In some embodiments, in order to further improve the light transmittance of the light-transmitting display region 211, the second connecting line 26 made of a transparent conductive material is used to connect the second light-emitting device 27 in the light-transmitting display region 211 to the second pixel drive circuit 25 in the conventional display region 212. In some embodiments, the transparent conductive material is indium tin oxide (ITO). The material of the first connecting line 23 includes at least one of metal and indium tin oxide.

In some embodiments, as shown in FIG. 6, which is a schematic structural diagram of a second connecting line according to some embodiments of the present disclosure. The plurality of second connecting lines 26 include at least two second connecting lines 26 with different lengths, and the plurality of second connecting lines 26 include a target connecting line 261. The length of the target connecting line 261 is a median of the lengths of the plurality of second connecting lines 26. A ratio of the area of the first connecting line 23 to the area of the target connecting line 261 ranges from 60% to 130%. In this way, the difference between the lighting time of the first light-emitting device 24 electrically connected to the first connecting line 23 and the lighting time of the second light-emitting device electrically connected to the second connecting line 26 is made small.

In some embodiments, the plurality of second connecting lines 26 include a target connecting line 261, and the length of the target connecting line 261 is a mean value of the lengths of the plurality of second connecting lines 26. The ratio of the area of the first connecting line 23 to the area of the target connecting line 261 ranges from 60% to 130%.

In some embodiments, as shown in FIG. 5, the connection line part 231 of the first connecting line 23 includes a first sub-connecting line 2311 and a second sub-connecting line 2312, wherein one end of the first sub-connecting line 2311 is connected to the first pixel drive circuit 22, one end of the second sub-connecting line 2312 is electrically connected to the first light-emitting device 24, and the compensation part 232 is respectively in contact with and electrically connected to the other end of the first sub-connecting line 2311 and the other end of the second sub-connecting line 2312. In this way, the first pixel drive circuit 22 is electrically connected to the second sub-connecting line 2312 through the first sub-connecting line 2311 and the compensation part 232, such that the difference between the lighting time of the first light-emitting device 24 and the lighting time of the second light-emitting device 27 electrically connected to the second connecting line 26 is small.

In some embodiments, as shown in FIG. 5, the compensation part 232 includes a threadlike compensation part 2321, wherein the shape of the threadlike compensation part 2321 includes at least one of an S-shaped winding shape and a polyline shape. In some embodiments, the threadlike compensation part 2321 is disposed in a blank region of the conventional display region 212 where no devices such as traces are disposed. The S-shaped winding shape and the polyline shape occupy a smaller space and have a larger area relative to a straight-line-shaped compensation part, thus the parasitic capacitance corresponding to the first connecting line 23 electrically connected to the first pixel drive circuit 22 is further increased, such that the difference value between the parasitic capacitance corresponding to the first connecting line 23 electrically connected to the first pixel drive circuit 22 and the parasitic capacitance corresponding to the second connecting line 26 electrically connected to the second pixel drive circuit 25 is small, thereby improving the display uniformity of the light-transmitting display region 211 and the conventional display region 211 on the display panel 20.

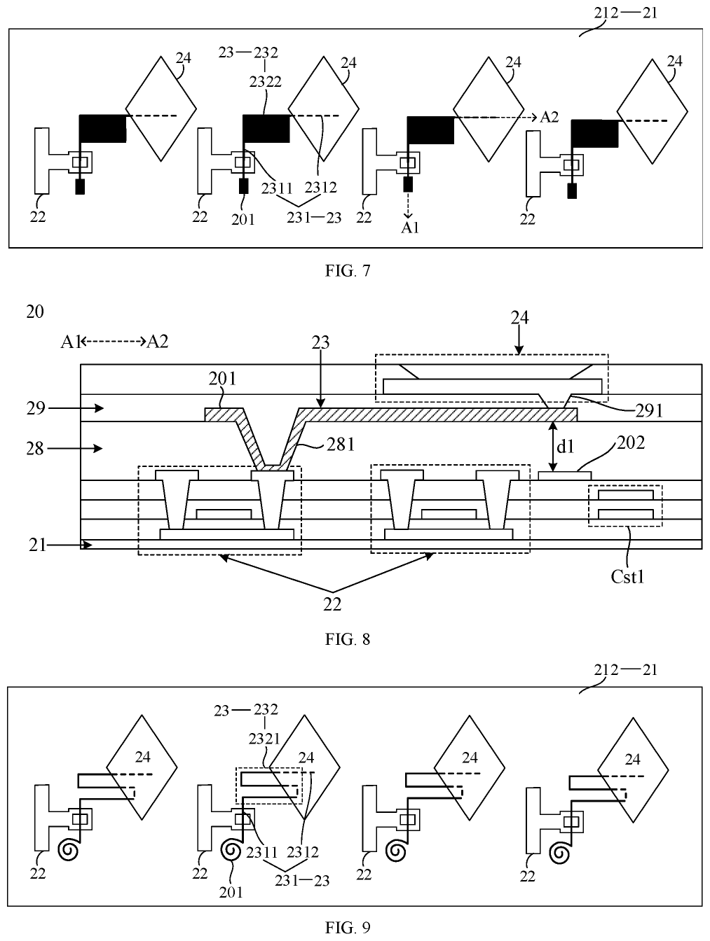

In some embodiments, as shown in FIG. 7, which is a schematic structural diagram of another first connecting line on the display panel according to some embodiments of the present disclosure, the compensation part 232 further includes a block-shaped compensation part 2322, wherein the shape of the block-shaped compensation part 2322 includes at least one of a rectangle, a triangle, a circle, and a hexagon. The shape of the block-shaped compensation part 2322 also includes other shapes such as a trapezoid. The block-shaped compensation part 2322 has a larger area than the threadlike compensation part 2321, and thus the parasitic capacitance corresponding to the first connecting line 23 electrically connected to the first pixel drive circuit 22 is further increased, such that the difference value between the parasitic capacitance corresponding to the first connecting line 23 electrically connected to the first pixel drive circuit 22 and the parasitic capacitance corresponding to the second connecting line 26 electrically connected to the second pixel drive circuit 25 is small, thereby further improving the display uniformity of the light-transmitting display region 211 and the conventional display region 211 on the display panel 20.

In some embodiments, as shown in FIG. 8, which is a schematic cross-sectional view of the display panel shown in FIG. 7 along A1-A2, the display panel 20 further includes a first insulating layer 28 and a second insulating layer 29, wherein the first pixel drive circuits 22, the first insulating layer 28, the first connecting line 23, the second insulating layer 29, and the first light-emitting device 24 are stacked in a direction away from the substrate 21. The first insulating layer 28 is provided with a first via hole 281 through which the first connecting line 23 is electrically connected to the first pixel drive circuit 22, and the second insulating layer 29 is provided with a second via hole 291 through which the first connecting line 23 is electrically connected to the first light-emitting device 24.

The distance between the first via hole 281 and the second via hole 291 in a plane perpendicular to the thickness direction of the substrate 21 is greater than or equal to 25 microns. Compared with the distance between the first via hole 281 and the second via hole 291 in a plane perpendicular to the thickness direction of the substrate 21 is 10 microns in the related art, the distance between the first via hole 281 and the second via hole 291 in the embodiments of the present disclosure is larger, such that the space for disposing the first connecting line 23 on the display panel 20 is larger, and thus the area of the first connecting line 23 is larger.

In some embodiments, the first pixel drive circuit 22 includes a plurality of thin film transistors, the first light-emitting device 24 is electrically connected to at least one of the plurality of thin film transistors, and an orthogonal projection of the first connecting line 23 on the substrate 21 overlaps with orthogonal projections of one or more thin film transistors on the substrate 21. In the embodiments of the present disclosure, the parasitic capacitance corresponding to the first connecting line 23 is increased by increasing the area of the first connecting line 23 and decreasing the distance between the first connecting line 23 and one or more thin film transistors.

In some embodiments, as shown in FIGS. 7 and 9, wherein FIG. 9 is a schematic structural diagram of another display panel according to some embodiments of the present disclosure, the first connecting line 23 further includes an extension part 201, wherein the extension part 201 is disposed on a side, distal from the compensation part 232, of the first sub-connecting line 2311, and the extension part 201 is electrically connected to the first sub-connecting line 2311. The shape of the extension part 201 includes at least one of a rectangle, a triangle, a circle, a hexagon, a straight-line shape, an S-shaped winding shape, and a polyline shape. Namely, it can be considered that the first connecting line 23 extends a specific distance along a direction away from the compensation part 232 at the connection portion with the first pixel drive circuit 22, and the extending part is the extension part 201. The parasitic capacitance corresponding to the first connecting line 23 electrically connected to the first pixel drive circuit 22 is further increased by means of the extension part 201, such that the difference value between the parasitic capacitance corresponding to the first connecting line 23 electrically connected to the first pixel drive circuit 22 and the parasitic capacitance corresponding to the second connecting line 26 electrically connected to the second pixel drive circuit 25 is small, thereby further improving the display uniformity of the light-transmitting display region 211 and the conventional display region 211 on the display panel 20.

In some embodiments, as shown in FIG. 8, the connection line parts 231 and the compensation parts 232 are in a same layer. The material of the connection line part 231 is the same as the material of the compensation part 232, and the connection line part 231 and the compensation part 232 are formed by one patterning process, so as to simplify the manufacturing processes of the display panel 20.

In some embodiments, the connection line part 231, the compensation part 232, and the extension part 201 are also in a same layer. The material of the extension part 201 is the same as the material of the connection line part 231, and the extension part 201, the connection line part 231, and the compensation part 232 are formed by one patterning process, so as to simplify the manufacturing processes of the display panel 20.

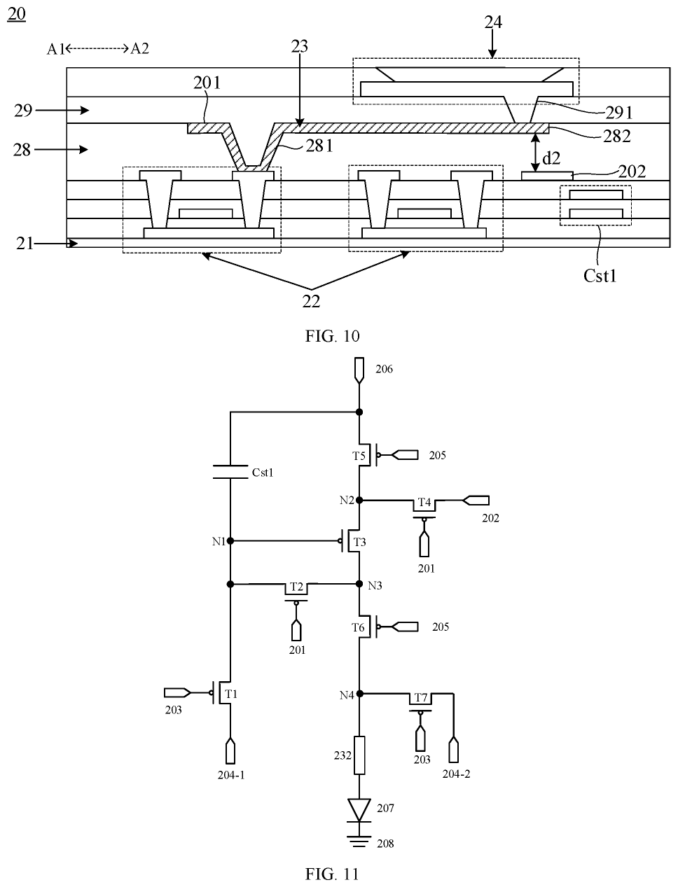

In some embodiments, as shown in FIG. 10, which is another schematic cross-sectional view of the display panel shown in FIG. 7 along A1-A2, because the second connecting line 26 includes traces in a plurality of layers, the overlapping area of the second connecting lines 26 in the plurality of layers is large, and thus the parasitic capacitances corresponding to the second connecting lines 26 are large. Thus, according to the formula C=εS/4πkd, where ε is the relative dielectric constant, S is the effective overlap area of capacitor plates, d is the distance between the capacitor plates, and k is the electrostatic force constant, in the case that the space for disposing the first connecting line 23 on the display panel 20 is limited, the parasitic capacitance between the first connecting line 23 and a target trace 202 (e.g., a power line or a data line) on the display panel 20 is increased through decreasing the distance between the first connecting line 23 and the target trace 202 on the display panel 20, wherein the target trace 202 is disposed on a side, proximal to the substrate 21, of the first connecting line 23.

In some embodiments, a side, distal from the substrate 21, of the first insulating layer 28 is provided with a groove 282, and at least part of the first connecting line 23 is disposed in the groove 282. Compared with the distance d1 between the first connecting line 23 and the target trace 202 on the display panel 20 shown in FIG. 8, in the display panel 20 shown in FIG. 10, the distance d2 between the first connecting line 23 and the target trace 202 on the display panel 20 is smaller by providing the groove 208. In addition, in some embodiments, by making the thickness of the first insulating layer 28 in other regions except for the groove 282 larger, the insulating effect of the first insulating layer 28 is better, and at the same time, the parasitic capacitance between the first connecting line 23 and the target trace 202 on the display panel 20 is increased.

In some embodiments, an orthogonal projection of the first connecting line 23 on the substrate 21 overlaps with an orthogonal projection of the groove 282 on the substrate 21. In this way, the influence of the groove 282 configured to accommodate the first connecting line 23 on the insulation property of the first insulating layer 28 is made small. Also, in some embodiments, the distance between the first connecting line 23 and the target trace 202 on the display panel 20 is further made small.

As shown in FIG. 10, the thickness of the first connecting line 23 is the same as the depth of the groove 282. The surface, on a side distal from the substrate 21, of the first connecting line 23 disposed in the groove 282 is flush with the upper edge, at a side distal from the substrate, of the groove 282. In this way, the groove 282 is filled up with the first connecting line 23 to reduce the influence of the first connecting line 23 on the flatness of the first insulating layer 28.

In some embodiments, in an exemplary implementation, as shown in FIG. 11, which is a circuit schematic diagram of a first pixel drive circuit according to some embodiments of the present disclosure, the first pixel drive circuit includes a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a capacitor structure Cst1. In some embodiments, the second pixel drive circuit has the same structure as the first pixel drive circuit. The display panel 20 further includes a capacitor structure (Cst1).

The first thin-film transistor T1 is a first initial thin-film transistor, the second thin-film transistor T2 is a compensation thin-film transistor, the third thin-film transistor T3 is a drive thin-film transistor, the fourth thin-film transistor T4 is a data writing transistor, the fifth thin-film transistor T5 is an operation control thin-film transistor, the sixth thin-film transistor T6 is an emission control thin-film transistor, and the seventh thin-film transistor T7 is a second initial thin-film transistor. It should be noted that, in some embodiments, T1 to T7 include a low-temperature poly-silicon (LTPS) thin-film transistor and/or an oxide thin-film transistor (O-TFT). T1 to T7 also can be other types of thin-film transistors, which are not limited in the embodiments of the present disclosure.

A gate of the third thin-film transistor T3 is connected to a first node N1, a source of the third thin-film transistor T3 is connected to a second node N2, a drain of the third thin-film transistor T3 is connected to a third node N3, and a drain of the sixth thin-film transistor is connected to a fourth node N4.

A gate of the fourth thin-film transistor T4 is connected to the gate line (Gate) 201, a source of the fourth thin-film transistor T4 is connected to the data signal line (Data) 202, and a drain of the fourth thin-film transistor T4 is connected to the second node N2.

A gate of the second thin-film transistor T2 is connected to the gate line 201, a source of the second thin-film transistor T2 is connected to the third node N3, and a drain of the second thin-film transistor T2 is connected to the first node N1.

A gate of the first thin-film transistor T1 is connected to a reset signal line (Reset) 203, a drain of the first thin-film transistor T1 is connected to a first reference signal line (Vinit) 204-1, and a source of the first thin-film transistor T1 is connected to the first node N1.

A gate of the fifth thin-film transistor T5 and a gate of the sixth thin-film transistor T6 are connected to a light emission signal line (EM) 205, a source of the fifth thin-film transistor T5 is connected to a constant-voltage high potential (VDD) 206, a drain of the fifth thin-film transistor T5 is connected to the second node N2, a source of the sixth thin-film transistor T6 is connected to the third node N3, a drain of the sixth thin-film transistor T6 is connected to an anode of a light-emitting device (OLED) 207, and a cathode of the light-emitting device 207 is connected to a low potential (VSS) 208.

A gate of the seventh thin film transistor T7 is connected to the gate line 201, a drain of the seventh thin film transistor T7 is connected to a second reference signal line 204-2, and a source of the seventh thin film transistor T7 is connected to the anode of the light-emitting device 207 through the compensation part, such that the capacitance between the N4 node and the anode of the light-emitting device 207 is large.

In some embodiments, one end of the capacitor structure Cst1 is connected to the first node N1, and the other end of the capacitor structure Cst1 is connected to a constant-voltage high potential 206.

In some embodiments, the voltage values of the first reference signal line 204-1 and the second reference signal line 204-2 are different. In some embodiments, the voltage values of the first reference signal line 204-1 and the second reference signal line 204-2 differ by 1 V to 5 V. Or, both the first reference signal line 204-1 and the second reference signal line 204-2 are connected to the same signal input terminal.

It should be noted that, in the present specification, in a case that the thin-film transistors having opposite polarities are used, or in a case that a current direction changes during the working of the circuit, the functions of the “source” and the “drain” described above may sometimes be interchanged. Therefore, in some embodiments of the present specification, “source” and “drain” are interchangeable with each other, which is not limited in the embodiments of the present disclosure.

In summary, the embodiments of the present disclosure provide a display panel. The display panel includes: a plurality of first pixel drive circuits, a plurality of second pixel drive circuits, a plurality of first connecting lines, and a plurality of first light-emitting devices disposed in a conventional display region of a substrate, a plurality of second connecting lines disposed on the substrate, and a plurality of second light-emitting devices disposed in a light-transmitting display region of the substrate. The first connecting line includes a connection line part and a compensation part electrically connected to each other, the area of the first connecting line is increased through the compensation part, and the parasitic capacitance corresponding to the first connecting line is compensated, such that the difference value of the parasitic capacitance corresponding to the first connecting line and the parasitic capacitance corresponding to the second connecting line is reduced. Therefore, the difference between the lighting time of the first light-emitting device electrically connected to the first pixel drive circuit and the lighting time of the second light-emitting device electrically connected to the second pixel drive circuit is made small, so that the display uniformity of the display panel is improved, and then the display effect of the display panel is improved.

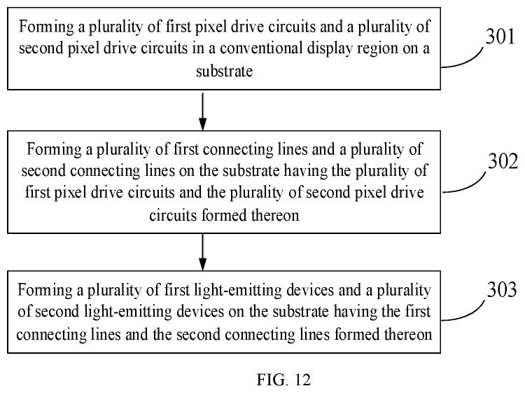

As shown in FIG. 12, which is a flowchart of a method for manufacturing a display panel according to some embodiments of the present disclosure, the method is used to manufacture the display panel 20 in any of the above embodiments, and the method for manufacturing the display panel 20 includes the following processes.

In process 301, a plurality of first pixel drive circuits and a plurality of second pixel drive circuits are formed in a conventional display region on a substrate.

In process 302, a plurality of first connecting lines and a plurality of second connecting lines are formed on the substrate having the plurality of first pixel drive circuits and the plurality of second pixel drive circuits formed thereon.

In the process, the first connecting line includes a connection line part and a compensation part, the compensation part being configured to increase the area of the first connecting line.

In process 303, a plurality of first light-emitting devices and a plurality of second light-emitting devices are formed on the substrate having the first connecting lines and the second connecting lines formed thereon.

In the process, the first light-emitting devices are disposed in the conventional display region of the substrate, and the second light-emitting devices are disposed in the light-transmitting display region of the substrate. The first light-emitting devices are electrically connected to the first pixel drive circuits through the first connecting lines, and the second light-emitting devices are electrically connected to the second pixel drive circuits through the second connecting lines.

In summary, the embodiments of the present disclosure provide a method for manufacturing a display panel. The display panel includes: a plurality of first pixel drive circuits, a plurality of second pixel drive circuits, a plurality of first connecting lines, and a plurality of first light-emitting devices disposed in a conventional display region of a substrate, a plurality of second connecting lines disposed on the substrate, and a plurality of second light-emitting devices disposed in a light-transmitting display region of the substrate. The first connecting line includes a connection line part and a compensation part electrically connected to each other, the area of the first connecting line is increased through the compensation part, and the parasitic capacitance corresponding to the first connecting line is compensated, such that the difference value of the parasitic capacitance corresponding to the first connecting line and the parasitic capacitance corresponding to the second connecting line is reduced. Therefore, the difference between the lighting time of the first light-emitting device electrically connected to the first pixel drive circuit and the lighting time of the second light-emitting device electrically connected to the second pixel drive circuit is made small, so that the display uniformity of the display panel is improved, and then the display effect of the display panel is improved.

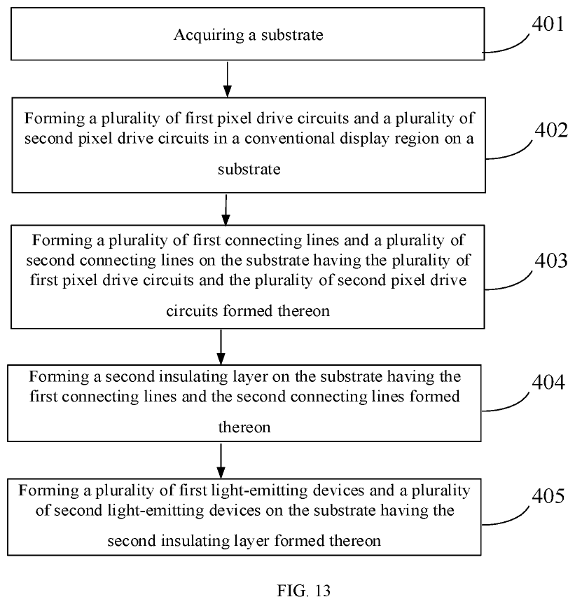

In some embodiments, as shown in FIG. 13, which is a flowchart of yet another method for manufacturing a display panel according to some embodiments of the present disclosure, the method is used to manufacture the display panel 20 in any of the above embodiments, and the method for manufacturing the display panel 20 includes the following processes.

In process 401, a substrate is acquired.

In some embodiments, the substrate is a flexible base substrate that is made of a flexible material (e.g., polyimide PI material). In some other embodiments, the substrate is a glass base substrate. In some other embodiments, the substrate is an opaque base substrate which includes a conventional display region and a light-transmitting display region.

In process 402, a plurality of first pixel drive circuits and a plurality of second pixel drive circuits are formed in a conventional display region on the substrate.

In some embodiments, the first pixel drive circuit has the same structure as the second pixel drive circuit, and the number of the second pixel drive circuits is smaller than the number of the first pixel drive circuits. In some embodiments, upon the first pixel drive circuits and the second pixel drive circuits being formed, a target traces electrically connected to the first pixel drive circuit and the second pixel drive circuit are further formed on the substrate, the target traces including a power line, a signal line, and the like.

In process 403, a plurality of first connecting lines and a plurality of second connecting lines are formed on the substrate having the plurality of first pixel drive circuits and the plurality of second pixel drive circuits formed thereon.

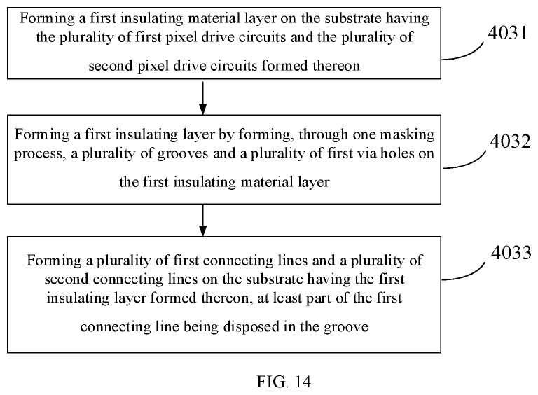

In the process, the first connecting line includes a connection line part and a compensation part, the compensation part being configured to increase the area of the first connecting line. In some embodiments, forming the plurality of first connecting lines on the substrate having the first insulating layer formed thereon includes: forming the plurality of first connecting lines by forming, through one patterning process, a plurality of the connection line parts and a plurality of the compensation parts on the substrate having the first insulating layer formed thereon to. As shown in FIG. 14, process 403 includes the following three sub-processes:

In sub-process 4031, a first insulating material layer is formed on the substrate having the plurality of first pixel drive circuits and the plurality of second pixel drive circuits formed thereon.

The material of the first insulating material layer includes at least one of silicon oxide (SiOx) and nitrogen oxide (SiNx).

In sub-process 4032, a first insulating layer is formed by forming, through one masking process, a plurality of grooves and a plurality of first via holes on the first insulating material layer.

In some embodiments, the mask used in the one masking process is a halftone mask, different regions on the halftone mask have different light transmittances, and grooves and first via holes with different depths are formed, by using the halftone mask, on the first insulating material layer, so as to simplify the manufacturing processes of the display panel.

In sub-process 4033, the plurality of first connecting lines and the plurality of second connecting lines are formed on the substrate having the first insulating layer formed thereon, at least part of the first connecting line being disposed in the groove.

At least part of the first connecting line is disposed in the groove, such that the distance between the first connecting line and the target trace is short, and then the parasitic capacitance between the first connecting line and the target trace is increased.

In process 404, a second insulating layer is formed on the substrate having the first connecting lines and the second connecting lines formed thereon.

In some embodiments, a second insulating material layer is first formed on the substrate having the first connecting lines and the second connecting lines formed thereon, and then second via holes are formed on the second insulating material layer to form the second insulating layer.

In process 405, a plurality of first light-emitting devices and a plurality of second light-emitting devices are formed on the substrate having the second insulating layer formed thereon.

In the process, the first light-emitting devices are disposed in the conventional display region of the substrate, and the second light-emitting devices are disposed in the light-transmitting display region of the substrate. The first light-emitting devices are electrically connected to the first pixel drive circuits through the first connecting lines, and the second light-emitting devices are electrically connected to the second pixel drive circuits through the second connecting lines.

In summary, the embodiments of the present disclosure provide a method for manufacturing a display panel. The display panel includes: a plurality of first pixel drive circuits, a plurality of second pixel drive circuits, a plurality of first connecting lines, and a plurality of first light-emitting devices disposed in a conventional display region of a substrate, a plurality of second connecting lines disposed on the substrate, and a plurality of second light-emitting devices disposed in a light-transmitting display region of the substrate. The first connecting line includes a connection line part and a compensation part electrically connected to each other, the area of the first connecting line is increased through the compensation part, and the parasitic capacitance corresponding to the first connecting line is compensated, such that the difference value of the parasitic capacitance corresponding to the first connecting line and the parasitic capacitance corresponding to the second connecting line is reduced. Therefore, the difference between the lighting time of the first light-emitting device electrically connected to the first pixel drive circuit and the lighting time of the second light-emitting device electrically connected to the second pixel drive circuit is made small, so that the display uniformity of the display panel is improved, and then the display effect of the display panel is improved.

Embodiments of the present disclosure further provide a display device, and the display device includes: any product or component with a display function, such as a mobile phone, a tablet computer, a television, a display, a notebook computer, a digital photo frame, and a navigator.

The display device includes: a photosensitive sensor and the display panel according to any one of the above embodiments, wherein the photosensitive sensor is any one of an image sensor in a camera, a light sensor, a distance sensor, or the like. In some embodiments, the image sensor is configured for face recognition, fingerprint recognition, or the like. An orthographic projection of a light inlet surface of the photosensitive sensor on the substrate of the display panel is within the light-transmitting display region.

In the present disclosure, the term “and/or” is only an association relationship that describes the associated objects, and indicates that there may be three relationships. For example, A and/or B indicate the following cases: only A is present, both A and B are present, and only B is present.

In the present disclosure, the term “at least one of A and B” merely describes the association relationship of the associated objects and indicates that three relationships may be present. For example, at least one of A and B may indicate the following cases: only A is present, both A and B are present, and only B is present. Similarly, “at least one of A, B, and C” indicates that seven relationships may be present and may indicate the following cases: only A is present, only B is present, only C is present, both A and B are present, both A and C are present, both C and B are present, and A, B, and C are all present. Similarly, “at least one of A, B, C, and D” indicates that fifteen relationships may be present and may indicate the following cases: only A is present, only B is present, only C is present, only D is present, both A and B are present, both A and C are present, both A and D are present, both C and B are present, both D and B are present, both C and D are present, A, B, and C are all present, A, B, and D are all present, A, C, and D are all present, B, C, and D are all present, and A, B, C, and D are all present.

It should be noted that, in the drawings, the sizes of the layers and regions may be exaggerated for clarity of illustration. Also, it can be understood that, in a case that an element or layer is referred to as being “on” another element or layer, it may be directly on the other element, or an intermediate layer may be present. In addition, it can be understood that, in a case that an element or layer is referred to as being “under” another element or layer, it may be directly under the other element, or one or more intermediate layers or elements may be present. In addition, it can also be understood that, in a case that a layer or element is referred to as being “between” two layers or elements, it may be the only layer between the two layers or elements, or one or more intermediate layers or elements may also be present. Like reference numerals refer to like elements throughout the present disclosure.

In the present disclosure, the terms “first,” “second,” “third,” and “fourth” are merely used for descriptive purposes and should not be construed as indicating or implying relative importance. The term “a plurality of” refers to two or more, unless otherwise explicitly defined.

The described above are merely optional embodiments of the present disclosure and are not intended to limit the present disclosure. Any modifications, equivalents, improvements, and the like, made within the concept and principle of the present disclosure should fall within the protection scope of the present disclosure.

1. A display panel, comprising:
a substrate, wherein the substrate comprises a light-transmitting display region and a conventional display region at a periphery of the light-transmitting display region;
a plurality of first pixel drive circuits, a plurality of first connecting lines, and a plurality of first light-emitting devices disposed in the conventional display region, wherein the first light-emitting devices are electrically connected to the first pixel drive circuits through the first connecting lines, and the first connecting line comprises a connection line part and a compensation part electrically connected to each other, the compensation part being configured to increase an area of the first connecting line; and
a plurality of second pixel drive circuits disposed in the conventional display region, a plurality of second connecting lines disposed on the substrate, and a plurality of second light-emitting devices disposed in the light-transmitting display region, wherein the second light-emitting devices are electrically connected to the second pixel drive circuits through the second connecting lines.

2. The display panel according to claim 1, wherein the plurality of second connecting lines comprise a target connecting line, wherein a length of the target connecting line is a median of lengths of the plurality of second connecting lines; and
a ratio of the area of the first connecting line to an area of the target connecting line ranges from 60% to 130%.

3. The display panel according to claim 1, wherein the plurality of second connecting lines comprise a target connecting line, wherein a length of the target connecting line is a mean value of lengths of the plurality of second connecting lines; and
a ratio of the area of the first connecting line to an area of the target connecting line ranges from 60% to 130%.

4. The display panel according to claim 1, wherein the connection line part comprises a first sub-connecting line and a second sub-connecting line, wherein one end of the first sub-connecting line is connected to the first pixel drive circuit, one end of the second sub-connecting line is electrically connected to the first light-emitting device, and the compensation part is respectively in contact with and electrically connected to the other end of the first sub-connecting line and the other end of the second sub-connecting line.

5. The display panel according to claim 1, wherein the compensation part comprises a threadlike compensation part, wherein a shape of the threadlike compensation part comprises at least one of an S-shaped winding shape and a polyline shape.

6. The display panel according to claim 1, wherein the compensation part comprises a block-shaped compensation part, wherein a shape of the block-shaped compensation part comprises at least one of a rectangle, a triangle, a circle, and a hexagon.

7. The display panel according to claim 1, further comprising a first insulating layer and a second insulating layer, wherein the first pixel drive circuits, the first insulating layer, the first connecting lines, the second insulating layer, and the first light-emitting devices are stacked in a direction away from the substrate; and
the first insulating layer is provided with a first via hole through which the first connecting line is electrically connected to the first pixel drive circuit, and the second insulating layer is provided with a second via hole through which the first connecting line is electrically connected to the first light-emitting device; wherein
a distance between the first via hole and the second via hole in a plane perpendicular to a thickness direction of the substrate is greater than or equal to 25 microns.

8. The display panel according to claim 4, wherein the first connecting line further comprises an extension part, wherein the extension part is disposed on a side, distal from the compensation part, of the first sub-connecting line, and the extension part is electrically connected to the first sub-connecting line; and
a shape of the extension part comprises at least one of a rectangle, a triangle, a circle, a hexagon, a straight-line shape, an S-shaped winding shape, and a polyline shape.

9. The display panel according to claim 1, wherein the connection line part and the compensation part are in a same layer.

10. The display panel according to claim 8, wherein the connection line part, the compensation part, and the extension part are in a same layer.

11. The display panel according to claim 1, further comprising a first insulating layer, wherein the first pixel drive circuits, the first insulating layer, and the first connecting lines are stacked in a direction away from the substrate; and
a side, distal from the substrate, of the first insulating layer is provided with a groove, and at least part of the first connecting line is disposed in the groove.

12. The display panel according to claim 11, wherein an orthographic projection of the first connecting line on the substrate overlaps with an orthographic projection of the groove on the substrate.

13. The display panel according to claim 11, wherein a thickness of the first connecting line is the same as a depth of the groove.

14. The display panel according to claim 11, wherein the first pixel drive circuit comprises a plurality of thin film transistors, wherein the first light-emitting device is electrically connected to at least one of the plurality of thin film transistors, and an orthographic projection of the first connecting line on the substrate has an overlapping area with orthographic projections of one or more of the plurality of thin film transistors on the substrate.

15. The display panel according to claim 11, further comprising a target trace, wherein the target trace is disposed on a side, proximal to the substrate, of the first insulating layer, and an orthographic projection of the first connecting line on the substrate has an overlapping area with an orthographic projection of the target trace on the substrate.

16. A method for manufacturing a display panel, comprising:
forming a plurality of first pixel drive circuits and a plurality of second pixel drive circuits in a conventional display region on a substrate;
forming a plurality of first connecting lines and a plurality of second connecting lines on the substrate having the plurality of first pixel drive circuits and the plurality of second pixel drive circuits formed thereon, the first connecting line comprising a connection line part and a compensation part, the compensation part being configured to increase an area of the first connecting line; and
forming a plurality of first light-emitting devices and a plurality of second light-emitting devices on the substrate having the first connecting lines and the second connecting lines formed thereon, the first light-emitting devices being disposed in the conventional display region of the substrate, and the second light-emitting devices being disposed in a light-transmitting display region of the substrate;
wherein the first light-emitting devices are electrically connected to the first pixel drive circuits through the first connecting lines, and the second light-emitting devices are electrically connected to the second pixel drive circuits through the second connecting lines.

17. The method according to claim 16, wherein forming the plurality of first connecting lines and the plurality of second connecting lines comprises:
forming a first insulating material layer on the substrate having the plurality of first pixel drive circuits and the plurality of second pixel drive circuits formed thereon;
forming a first insulating layer by forming a plurality of grooves and a plurality of first via holes on the first insulating material layer through a single masking process; and
forming the plurality of first connecting lines and the plurality of second connecting lines on the substrate having the first insulating layer formed thereon, at least part of the first connecting line being disposed in the groove.

18. The method according to claim 17, wherein forming the plurality of first connecting lines on the substrate having the first insulating layer formed thereon comprises:
forming the plurality of first connecting lines by forming, through one patterning process, a plurality of the connection line part and a plurality of the compensation parts on the substrate having the first insulating layer formed thereon.

19. The method according to claim 16, wherein forming the plurality of first light-emitting devices and the plurality of second light-emitting devices on the substrate having the first connecting lines and the second connecting lines formed thereon comprises:
forming a second insulating layer on the substrate having the first connecting lines and the second connecting lines formed thereon, the second insulating layer being provided with a second via hole; and
forming the plurality of first light-emitting devices and the plurality of second light-emitting devices on the substrate having the second insulating layer formed thereon.

20. A display device, comprising: a photosensitive sensor and a display panel, wherein the display panel comprises:
a substrate, wherein the substrate comprises the light-transmitting display region and a conventional display region at a periphery of the light-transmitting display region;
a plurality of first pixel drive circuits, a plurality of first connecting lines, and a plurality of first light-emitting devices disposed in the conventional display region, wherein the first light-emitting devices are electrically connected to the first pixel drive circuits through the first connecting lines, and the first connecting line comprises a connection line part and a compensation part electrically connected to each other, the compensation part being configured to increase an area of the first connecting line; and
a plurality of second pixel drive circuits disposed in the conventional display region, a plurality of second connecting lines disposed on the substrate, and a plurality of second light-emitting devices disposed in the light-transmitting display region, wherein the second light-emitting devices are electrically connected to the second pixel drive circuits through the second connecting lines; and
an orthographic projection of a light inlet surface of the photosensitive sensor on the substrate of the display panel is within the light-transmitting display region.
